(19) United States
(12) Patent Application Publication
(10) Pub. No.: US 2012/0194172 A1
(43) Pub. Date: Aug. 2, 2012

(54) Current Sensing Apparatus

(76) Inventors: Raymond Gregory Wallace, JR., Francestown, NH (US); Eric Christopher Beishline, Marlborough, MA (US); Jeffrey Alan Herb, Vancouver, WA (US); Tiago Braz Anes, Framingham, MA (US)

(21) Appl. No.: 13/354,845

(22) Filed: Jan. 20, 2012

Related U.S. Application Data
(60) Provisional application No. 61/437,261, filed on Jan. 28, 2011.

(51) Int. Cl. G01R 1/20

(52) U.S. Cl. 324/126

(57) ABSTRACT

A current sensing device (50) having a plurality of discrete, repeatable, user-selectable setpoint values. Current sensing circuitry (32) of the device includes a multi-position switch (34) operative to alternatively connect discrete impedances (e.g. resistors R₁, R₂, R₃, or R₄) into the circuit in order to change the setpoint value. A calibration scale (42) associated with a user-input knob (44) of the multi-position switch may be marked with values of horsepower which correspond to the size of a motor that has a motor nameplate rating equivalent to the sensed current setpoint associated with each switch position. A second switch (52) may be provided to allow the user to select an offset for the setpoint value.

This application claims benefit of the 28 Jan. 2011 filing date of U.S. provisional patent application No. 61/437,261.

### FIELD OF THE INVENTION

This invention relates generally to the field of current sensors and current sensing switches, and more particularly to devices that may be associated with a conductor for detecting the current passing through the conductor and that may be adjusted to change state over a range of user-selectable sensed current setpoint values.

### BACKGROUND OF THE INVENTION

Current sensors and current switches are well known in the art and are often used in conjunction with a motor or other operating device to monitor the operating status of the operating device. The current sensing apparatus typically includes an inductive coil which generates a current in a secondary circuit responsive to a changing magnetic field generated by alternating current passing through a primary conductor providing power to the operating device. That responsive current is then processed to provide an output and/or control signal indicative of the current being supplied to the operating device. When used as a current switch, the current sensing apparatus will open or close a contact in the secondary circuit at a predetermined, user-selectable current value (setpoint) associated with the primary conductor.

Current sensing switches are available in a variety of styles and power levels and with a variety of user interface features. Examples include the time delay relays commercially available from Magnecraft Electric Company of Chicago, Ill., such as Magnecraft's Model 840 Series relays commercially available since at least 2006. FIG. 1 illustrates the features of one particular model in that prior art series of relays (i.e., a Model 841 current sensing relay, generally indicated at reference numeral 10. The relay 10 includes a housing 12 that is configured to mount to a DIN rail 14 of an electrical equipment rack (not shown). The relay 10 includes input terminals 15 (for the power circuit being monitored) and an associated green LED indicator light 16, as well as output terminals 18 (for the secondary circuit being switched) and an associated red LED indicator 20. The relay 10 also includes two user interface input devices; a rotatable current sensing adjustment knob 22 and a rotatable time delay adjustment knob 24. The current sensing adjustment knob 22 is surrounded by a calibration scale 26 which includes indications from 10% to 100%, thereby allowing the user to set a potentiometer for the relay 10 (as described more fully hereinafter) to any trip setpoint value within a range of values from 10% to 100% of the rated sensing current value. The time delay adjustment knob 24 is also surrounded by a calibration scale 28 for setting a potentiometer, which allows the user to select a time delay of anywhere within a range from 0 to 10 seconds between when the sensed current achieves the selected setpoint and when the transfer of contacts in the secondary circuit occurs.

Digital current sensing devices are now commonplace. Digital devices include an interface which allows the user to make setpoint adjustments digitally rather than by manipulating an adjustment knob on the device itself. Accordingly, digital devices are generally more precise than devices which incorporate manually adjustable potentiometers, such as those associated with the current sensing adjustment knob 22 and time delay adjustment knob 24 of the device of FIG. 1. However, digital devices are also generally more expensive than devices using manually adjustable potentiometers.

### BRIEF DESCRIPTION OF THE DRAWINGS

The invention is explained in the following description in view of the drawings that show:

FIG. 1 is a perspective view of a prior art current sensing apparatus.

FIG. 2 is a partial schematic illustration of a circuit with a potentiometer for adjusting the current sensing setpoint of the prior art apparatus of FIG. 1.

FIG. 3 is a partial schematic illustration of a circuit in accordance with an embodiment of the invention with a multi-position switch used to adjust the current sensing setpoint.

FIG. 4 is a top view of a current switch in accordance with an embodiment of the invention that is enabled for use with motors of a range of horsepower ratings.

FIG. 5 is a partial schematic illustration of a circuit in accordance with an embodiment of the invention with a first multi-position switch used to adjust the current sensing setpoint and a second multi-position switch used to adjust an offset value for the setpoint.

### DETAILED DESCRIPTION OF THE INVENTION

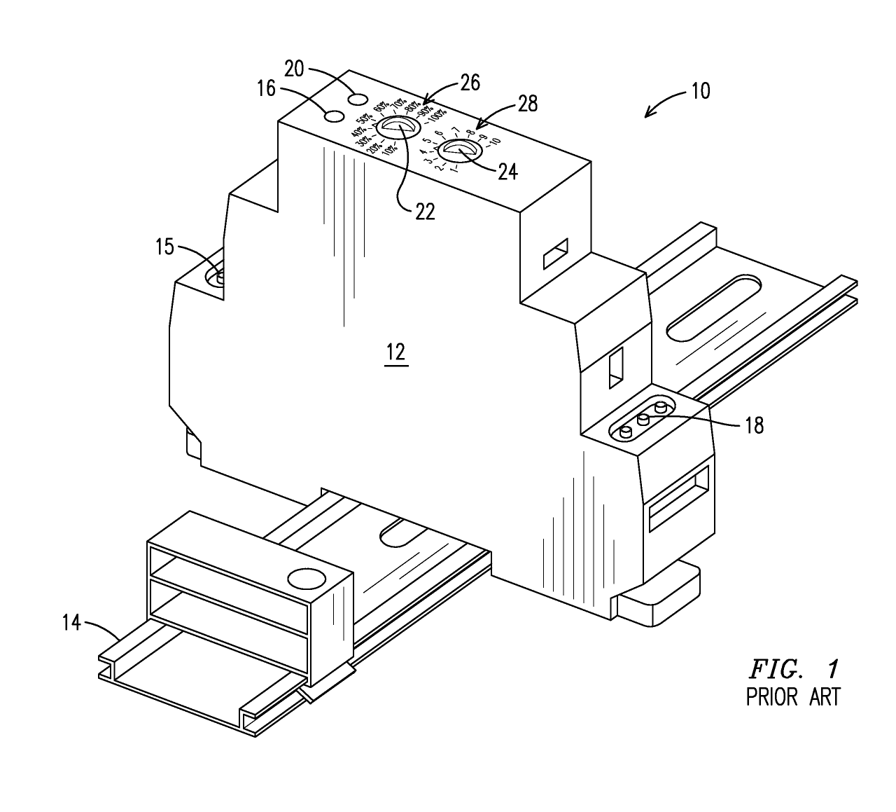

The present inventors have recognized a need for achieving an improved accuracy and repeatability in current sensing devices without having to incur the increased cost typically associated with digital devices. The present inventors have also recognized that a degree of inaccuracy is generated in devices such as those shown in FIG. 1 due to the inherent imprecision associated with positioning the calibration scales 26, 28 on the housing 12 and the inherent imprecision associated with mounting the potentiometers and knobs 22, 24 to the housing 12. Furthermore, the analog nature of a potentiometer creates imprecision when attempting to set the knob 22, 24 to a value that is in between two of the values printed on the calibration scale 26, 28. These inaccuracies can stack up and become increasingly significant when the device uses a single turn potentiometer where the total range of available setpoint values is limited to something less than 360 degrees of angular displacement of a knob, such as in the device described in U.S. Patent Application Publication US2010/0321032 A1.

To overcome these problems, the present inventors have developed a current sensing device which provides for manual adjustment of the current sensing setpoint (or other user input variable) by means of a multi-position switch rather than with the potentiometer of the prior art.. Whereas prior art devices adjust the setpoint by means of a potentiometer having a continuously variable range of resistances, a device in accordance with an embodiment of the present invention adjusts the setpoint by means of a multi-position switch, where each switch position is associated with a different impedance (resistance) value. Thus, whereas the prior art device can be adjusted to any setpoint value within a range of setpoint values as depicted on the calibration scale (such as anywhere between 10-100%) with a degree of uncertainty, a device in accordance with an embodiment of the present invention may be adjusted only to discrete pre-determined setpoint values (such as 10%, 20%, 30% . . . 90%, 100%), but with more precision and repeatability than with prior art devices. When used in applications with motors or other load devices that draw a constant operating current, the use of a prior art current switch with a potentiometer will result in a degree of uncertainty and difference each time the setpoint is set, while use of a current switch with the circuit described herein will result in a precise and repeatable setpoint limited only by the tolerance of the discrete devices used to set the necessary impedance; e.g. fixed resistors in one embodiment. Fixed resistors are commonly available with tolerances of 1%, 5% and 10% at very low cost, while potentiometers with tolerances below 30% are much more costly.

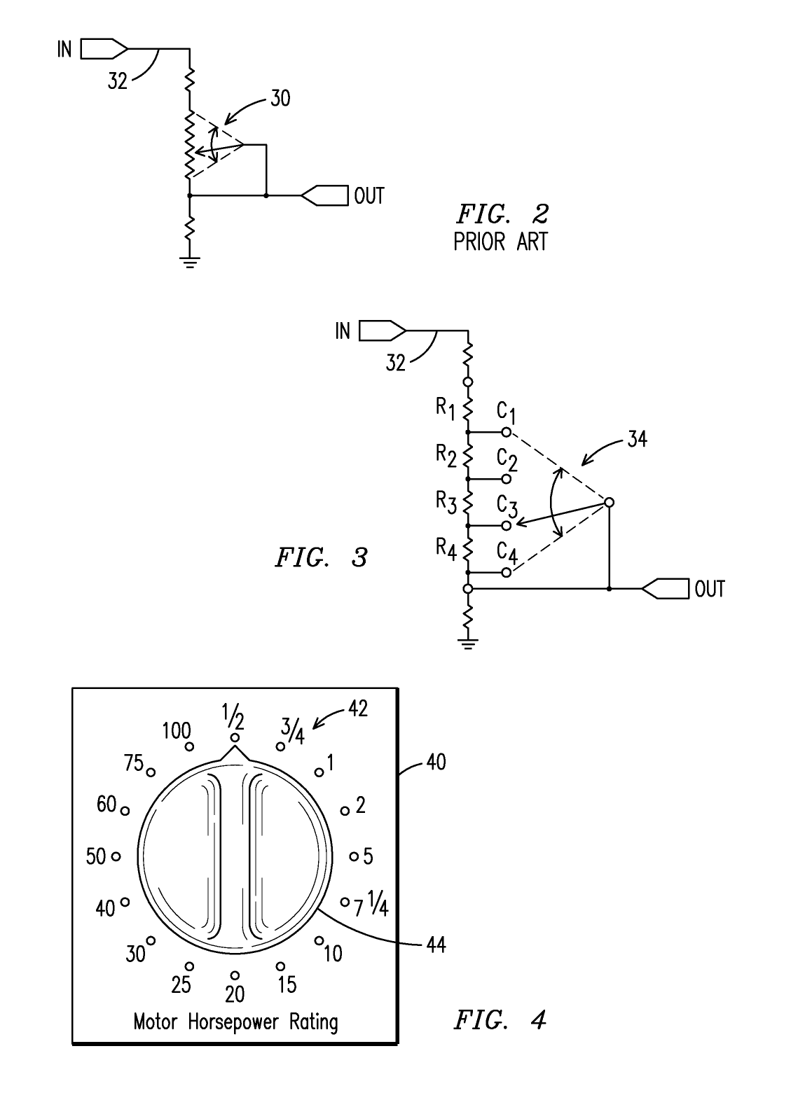

FIG. 2 is a portion of a schematic of a current switch illustrating a potentiometer 30 incorporated into a current sensing circuit 32 of the prior art current sensing device 10 of FIG. 1. In order to change the setpoint of the device, the potentiometer 30 may be moved along a range of resistance values, as indicated by the double-headed arrow, by user-actuation of an adjustment knob, such as the current sensing adjustment knob 22 of FIG. 1.

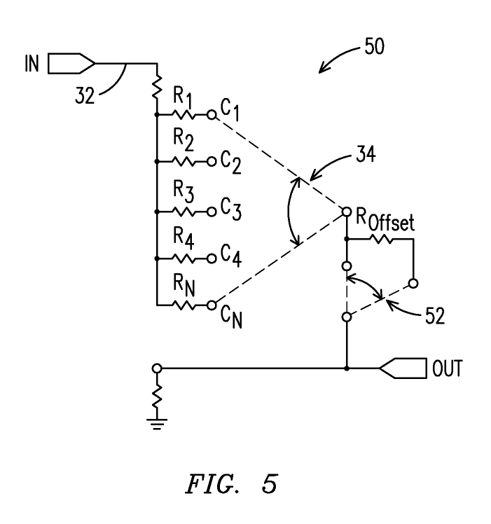

In contrast, FIG. 3 is a portion of a schematic of a current switch in accordance with one embodiment of the present invention. The current sensing circuit 32 now includes a multi-position switch 34 which may be moved among four positions to selectively activate any one of four contacts C₁, C₂, C₃, or C₄. The various contacts of the switch 34 selectively (and in this embodiment, sequentially) include discrete resistors R₁, R₂, R₃, and R₄ into the circuit 32. One will appreciate that in other embodiments there may be any number of contacts greater than one, and that impedances of different values may be individually connected into the circuit 32 (as later illustrated in FIG. 5) rather than sequentially activated as shown in FIG. 3.

The embodiments described herein utilize current sensing circuitry that provides a change in state of an output at a selected setpoint of sensed current, with the selection of setpoint being implemented in the circuitry by changing the value of a impedance (resistance) in the circuitry. For simplicity, FIG. 3 illustrates the use of discrete resistors alone to change impedance. One skilled in the art will appreciate that in other embodiments, in lieu of using discrete resistors (R₁, R₂, R₃, and R₄) in series and/or parallel to change impedance (Z₁, Z₂, Z₃, and Z₄), capacitors and/or resistors combined in series and/or parallel or other types of electrical components may be selectively connected by the switch to provide for a stepped change in impedance, capacitance or other electrical parameter in order to change the setpoint.

Advantageously, the present invention eliminates the inaccuracies of known current sensing devices associated with the mounting of potentiometers, with the placement of calibration scales relative to a positioning knob of the potentiometer, and with the selection of a value that is in between marked values on the calibration scale. The adjustment circuit described also exhibits a high degree of repeatability that is not available in circuits using potentiometers as the adjustment component. This is particularly advantageous when it becomes necessary to change the setpoint of a current switch during testing of a system, and then to return the current switch to the original setpoint. A device in accordance with an embodiment of this invention has the ability to be reset to the previous setpoint precisely, while a prior art device employing a potentiometer can be returned to only an approximation of the original setpoint.

Furthermore, the present invention allows a single current sensing device to be used for a wider range of sensed currents than are single prior art devices. Single turn potentiometers are readily available with only a relatively limited range of resistance values from end turn to end turn. This range of resistance values limits the maximum range of current value setpoints that may be accommodated by a single current sensing device. For example, a typical prior art current switch is able to accommodate the range of Full Load Amperage (FLA) currents drawn by motors ranging from ½ horsepower to 60 horsepower (typically 2.2 amps to 154 amps for 230 VAC motors). Higher FLA setpoints as may be needed for commonly available larger motors, such as 75 or 100 horsepower (up to 248 amps at 230 VAC), would require resistance values that unacceptably limit the accuracy of the current switch when used on the low current end of the range of the potentiometer necessary for the ½ horsepower setting. A current switch built in accordance with an embodiment of the present invention would not be so limited, since any desired range of current setpoints may be providing by changing the value of the fixed impedances using resistors (such as R₁, R₂, R₃, and R₄ of FIG. 3) that are selectively connected by the multi-position switch 34. In one embodiment, a range of motors from ½ horsepower to 100 horsepower may be accommodated by a single current switch by appropriate selection of the corresponding fixed impedance (resistor) values.

Prior art current sensing devices with user-selectable setpoint values are typically supplied with calibration scales that are marked in units of amperage, or alternatively with units of percentage of a rated current value. The present inventors have innovatively recognized that a calibration scale that is marked in units of horsepower may be applied to a current switch for use with a variety of sizes of electrical motors. A scaling factor is applied to correlate a rated current value for each respective motor size to a position of the user-operated current setpoint adjustment device, e.g. potentiometer or multi-position switch. Such a current sensing device 40 is illustrated in FIG. 4 to have precise switch-selectable FLA values corresponding to each of sixteen motor ratings ranging from ½ to 100 horsepower. Each of these sixteen selectable setpoint values are displayed on a calibration scale 42 positioned proximate a knob 44, which is the user input member of a multi-position switch incorporated into the current sensing circuit of the device. Multi-position switches having 2, 3, 5, 10 or 16 positions are commonly available, thus facilitating the manufacturing of current sensing devices that provide a choice of two, three, five, ten or sixteen setpoints. A different fixed impedance is associated with each of the alternatively selectable contacts of the switch, with alternative ones of the fixed impedances being connected into the current sensing circuit to provide respective alternative current value setpoints by movement of the knob 44. In another embodiment, more than sixteen selections may be accommodated by using two multi-position switches or a custom multi-position switch. One may appreciate that the range of impedances (resistances) necessary to achieve such diverse and numerous discrete current setpoints are not possible with a prior art device utilizing a single turn potentiometer.

The present invention may be used with any type of current sensing device where a precise, repeatable, user-selectable setpoint is desired. The user-operated setpoint selection knob may be associated with a calibration scale having any desired units of measurement, such as: horsepower ratings as illustrated in FIG. 4; Full Load Amperage values; watts; volt-amperes (VA); or percentages of a rated current value (i.e. 10%, 20%, 30%, 40% . . . 90%, 100%), for example. Known current sensing devices typically include a fixed offset (dead zone) value in any selectable setpoint value. For example, a current switch having selectable FLA values may be designed to trip at 7.6 amperes when set to an 8 ampere setting for a loss-of-flow application, thus providing a 5% buffer from the target current value to accommodate normal variation (hysteresis) in the actual current draw of a motor rated at 8 amperes.

The present invention allows for simple implementation of a current sensing device where the offset value is either designed into the device as part of the specific impedance value selection or is selectable by the user, such as by moving a second multi-position switch which functions to incorporate a second impedance (resistance) value into the current sensing circuit in parallel to the selectable fixed impedance resistors. This feature may be especially useful when using a single current sensing device for different applications, such as alternatively with a motor or with lighting or with an electrical heater, since the offset value desired with each of these applications may be different. FIG. 5 illustrates one such current sensing device 50 where a first multi-position switch 34 may be moved among N number positions to selectively activate any one of N contacts C₁, C₂, C₃, C₄ to C_{N}. The various contacts of the first switch 34 selectively (and in this embodiment, individually) include discrete resistors R₁ through R_{N} into the circuit 32. A second multi-position switch 52 selectively includes an offset resistor R_{OFFSET} into the circuit 32 in order to allow the user to select or deselect an offset value for the selected setpoint.

While various embodiments of the present invention have been shown and described herein, it will be obvious that such embodiments are provided by way of example only. Numerous variations, changes and substitutions may be made without departing from the invention herein. Accordingly, it is intended that the invention be limited only by the spirit and scope of the appended claims.

The invention claimed is:

1. A current sensing device comprising:
a current sensing circuit for sensing a level of current carried in a conductor and responsive to a connected impedance value to provide a sensed current value setpoint;
a multi-position switch comprising a plurality of alternatively selectable contacts associated with the current sensing circuit; and
an impedance associated with each of the alternatively selectable contacts, with the value of each impedance differing from the value of other impedances, and with the multi-position switch operating to connect alternative ones of the impedances into the current sensing circuit to provide respective alternative sensed current value setpoints.

2. The current sensing device of claim 1, further comprising a calibration scale disposed proximate to a user input member of the multi-position switch, the calibration scale displaying a current setpoint value associated with each alternative position of the user input member.

3. The current sensing device of claim 1, further comprising a calibration scale disposed proximate to a user input member of the multi-position switch, the calibration scale displaying a horsepower value associated with each respective sensed current value setpoint.

4. The current sensing device of claim 1, wherein the multi-position switch comprises at least five contacts.

5. The current sensing device of claim 1, wherein the multi-position switch comprises at least ten contacts.

6. The current sensing device of claim 1, wherein the multi-position switch comprises at least sixteen contacts.

7. The current sensing device of claim 1, further comprising a fixed resistance associated with each of the alternatively selectable contacts, with a value of each fixed resistance differing from the value of other ones of the fixed resistances.

8. The current sensing device of claim 7, wherein each fixed resistance comprises a different fixed resistor.

9. The current sensing device of claim 7, wherein each fixed resistance comprises a different subset of a plurality of fixed resistors.

10. The current sensing device of claim 1, further comprising a second switch associated with the current sensing circuit, the second switch operating to selectively connect an offset resistance into the current sensing circuit.

11. A current sensing device comprising:
a housing;
circuitry within the housing operative to sense current in a nearby conductor and to change a state of an output at a setpoint value of sensed current;
a multi-position switch mounted to the housing and electrically associated with the circuitry;
a plurality of electrical components selectively connected to the circuitry via alternative contacts of the multi-position switch, the setpoint value responsive to a selection of ones of the electrical components connected to the circuitry via alternative positions of the multi-position switch; and
a calibration scale disposed on the housing proximate a user-input element of the multi-position switch to indicate a parameter associated with the setpoint value for each respective position of the multi-position switch.

12. The current sensing device of claim 11, wherein the calibration scale is marked in units of horsepower.

13. The current sensing device of claim 11, further comprising a second switch associated with the circuitry, the second switch operating to selectively connect an offset resistance into the circuitry.

14. A current sensing device comprising:
a current sensing circuit responsive to a sensed current to change an output state; and
a multi-position user-operated current setpoint adjustment device associated with the current sensing circuit and operable to change the sensed current at which the change in output state occurs;
wherein the adjustment device is marked in units of horsepower scaled to respective horsepower values associated with each of a plurality of alternative electrical motors that may be used with the current sensing device.

15. The current sensing device of claim 14, wherein the adjustment device comprises a multi-position switch operable to connect into the current sensing circuit alternative selected ones of a discrete impedance value associated with each respective position of the multi-position switch effective to scale the sensed current at which the change in output state occurs for each respective position of the multi-position switch to a value associated with a full load amperage rating of the respective electrical motor associated with each respective switch position.

16. The current sensing device of claim 15, further comprising a fixed resistance associated with each of the discrete impedance values, with a value of each fixed resistance differing from the value of other ones of the fixed resistances.

17. The current sensing device of claim 16, wherein each fixed resistance comprises a different fixed resistor.

18. The current sensing device of claim 16, wherein each fixed resistance comprises a different subset of a plurality of fixed resistors.

19. The current sensing device of claim 1, further comprising a second user-operated device associated with the current sensing circuit, the second user-operated device operating to selectively connect an offset resistance into the current sensing circuit.
